(19) United States
(12) Patent Application Publication
(10) Pub. No.: US 2026/0173872 A1
(43) Pub. Date: Jun. 18, 2026

(54) SEMICONDUCTOR PACKAGING USING A LOW DIELECTRIC CONSTANT POLYMER IN TARGETED AREAS IN CONJUNCTION WITH A HEAT-TRANSFER ENHANCED POLYMER

(71) Applicant: Microchip Technology Incorporated, Chandler, AZ (US)

(72) Inventors: Steve Nagel, Chandler, AZ (US); Bomy Chen, Newark, CA (US)

(73) Assignee: Microchip Technology Incorporated, Chandler, AZ (US)

(21) Appl. No.: 19/048,212

(22) Filed: Feb. 7, 2025

Related U.S. Application Data
(60) Provisional application No. 63/735,327, filed on Dec. 18, 2024.

(51) Int. Cl. H10W 40/25; H10W 74/47

(52) U.S. Cl. CPC H10W 40/251; H10W 74/473

(57) ABSTRACT

A system and method for a polymer with a low dielectric constant applied in targeted areas of a semiconductor using additive manufacturing and a second polymer having high thermal conductivity encasing the entire semiconductor are disclosed. The method may include applying, using an additive manufacturing technique, a first polymer to a first area of a semiconductor die. The first polymer may include a first filler having a dielectric constant of 3.3 or less. The method may also include applying a second polymer over the first polymer and encapsulating the semiconductor die. The second polymer may be different from the first polymer.

This application claims priority to U.S. Provisional Patent Application No. 63/735,327 filed December 18, 2024, the contents of which are hereby incorporated in their entirety.

### TECHNICAL FIELD

The present disclosure relates to semiconductor packaging and, in particular, to a polymer including a low dielectric constant in targeted areas of a semiconductor die using additive manufacturing and encasing the semiconductor die with a second polymer having a high thermal conductivity.

### BACKGROUND

Semiconductor packaging is the process of encasing a semiconductor chip in a protective material that also provides electrical connections to external components. Epoxy molding is a process in semiconductor packaging where a liquid epoxy resin is used to encapsulate and protect electronic components, like integrated circuits (ICs). This process provides benefits such as protection, electrical insulation, heat dissipation, and mechanical strength.

The epoxy resins used in semiconductor packaging are specially formulated compounds called epoxy molding compounds (EMCs). These compounds typically contain a base resin that provides the structure and protective properties and fillers (e.g., silicon dioxide) to control thermal expansion, improve mechanical strength, and enhance thermal conductivity.

### SUMMARY OF THE INVENTION

Aspects provide systems and methods for a polymer including a low dielectric constant in targeted areas of a semiconductor die using additive manufacturing and encasing the semiconductor die with a second polymer having a high thermal conductivity. Examples of the present disclosure may include an apparatus. The apparatus may include a semiconductor die. The apparatus may also include a first polymer applied to a first area of the semiconductor die. The first polymer may include a first filler having a dielectric constant of 3.3 or less. The apparatus may further include a second polymer encapsulating the semiconductor die and the first polymer. The second polymer may be different from the first polymer.

In combination with any of the above examples, the second polymer may include a second filler having a thermal conductivity less than 2200 Watts per meter-Kelvin at 0^{o} Kelvin.

In combination with any of the above examples, the second filler may include at least one of aluminum oxide (Al2O3), aluminum, aluminum nitride (AlN), boron nitride (BN), silicon dioxide, or diamond.

In combination with any of the above examples, the first polymer may be applied to the first area using an additive manufacturing technique.

In combination with any of the above examples, the first filler having the dielectric constant 3.3 or less may be created by a process including: applying a first layer of a first material on a silicon base, applying a second layer of a second material on the first layer of the first material, applying a third layer of the first material on the second layer of the second material, and wet etching the first layer, the second layer, and the third layer to create a plurality of balls of the first filler.

In combination with any of the above examples, the first area of the semiconductor die may be selected based on at least one of an expected noise or an expected parasitic capacitance of the semiconductor die.

In combination with any of the above examples, the first area of the semiconductor die may be adjacent to a transistor on the semiconductor die.

In combination with any of the above examples, the first area of the semiconductor die may be an intermediate layer of a redistribution layer.

Alone or in combination with any of the above examples, examples of the present disclosure may include a method. The method may include applying, using an additive manufacturing technique, a first polymer to a first area of a semiconductor die. The first polymer may include a first filler having a dielectric constant of 3.3 or less. The method may also include applying a second polymer over the first polymer and encapsulating the semiconductor die. The second polymer may be different from the first polymer.

In combination with any of the above examples, the second polymer may include a second filler having a thermal conductivity less than 2200 Watts per meter-Kelvin at 0^{o} Kelvin.

In combination with any of the above examples, the second filler may include at least one of aluminum oxide (Al2O3), aluminum, aluminum nitride (AlN), boron nitride (BN), silicon dioxide, or diamond.

In combination with any of the above examples, the method may include creating the first filler by applying a first layer of a first material on a silicon base. The method may also include applying a second layer of a second material on the first layer of the first material. The method may additionally include applying a third layer of the first material on the second layer of the second material. The method may further include wet etching the first layer, the second layer, and the third layer to create a plurality of balls of the first filler.

In combination with any of the above examples, the method may include selecting the first area of the semiconductor die based on at least one of an expected noise or an expected parasitic capacitance of the semiconductor die.

In combination with any of the above examples, the first polymer may be applied adjacent to a transistor on the semiconductor die.

In combination with any of the above examples, the first polymer may be applied on an intermediate layer of a redistribution layer.

Alone or in combination with any of the above examples, examples of the present disclosure may include a semiconductor die made by a process including applying, using an additive manufacturing technique, a first polymer to a first area of a semiconductor die. The first polymer may include a first filler having a dielectric constant of 3.3 or less. The process may also include applying a second polymer over the first polymer and encapsulating the semiconductor die. The second polymer may be different from the first polymer.

In combination with any of the above examples, the second polymer may include a second filler having a thermal conductivity less than 2200 Watts per meter-Kelvin at 0^{o} Kelvin.

In combination with any of the above examples, the semiconductor die may be made by the process including creating the first filler by applying a first layer of a first material on a silicon base. The process may also include applying a second layer of a second material on the first layer of the first material. The process may additionally include applying a third layer of the first material on the second layer of the second material. The process may further include wet etching the first layer, the second layer, and the third layer to create a plurality of balls of the first filler.

In combination with any of the above examples, the first polymer may be applied adjacent to a transistor on the semiconductor die.

In combination with any of the above examples, the first polymer may be applied on an intermediate layer of a redistribution layer.

### BRIEF DESCRIPTION OF THE DRAWINGS

The figures illustrate examples of systems and methods for a polymer including a low dielectric constant in targeted areas of a semiconductor die using additive manufacturing and encasing the semiconductor die with a second polymer having a high thermal conductivity.

FIGS. 1A and 1B illustrate top and side views, respectively, of a semiconductor die packaged using a first polymer having a low dielectric constant filler in targeted areas, according to examples of the present disclosure;

FIGS. 2A and 2B illustrate top and side views, respectively, of a redistribution layer in a panel level package, according to examples of the present disclosure;

FIGS. 3A, 3B, and FIG. 3C illustrate the creation of a filler for a polymer having a low dielectric constant, according to examples of the present disclosure;

FIG. 4 illustrates a method performed for providing a polymer including a low dielectric constant in targeted areas of a semiconductor using additive manufacturing and encasing the semiconductor die with a second polymer having a high thermal conductivity, according to examples of the present disclosure; and

FIG. 5 illustrates a more-detailed method performed for providing a polymer including a low dielectric constant in targeted areas of a semiconductor die using additive manufacturing and encasing the semiconductor die with a second polymer having a high thermal conductivity, according to examples of the present disclosure.

The reference number for any illustrated element that appears in multiple different figures has the same meaning across the multiple figures, and the mention or discussion herein of any illustrated element in the context of any particular figure also applies to each other figure, if any, in which that same illustrated element is shown.

### DESCRIPTION

According to an aspect of the invention, systems and methods for a polymer including a low dielectric constant in targeted areas of a semiconductor die using additive manufacturing and encasing the semiconductor die with a second polymer having a high thermal conductivity are provided. A polymer including a low dielectric constant filler may be applied in targeted locations on a semiconductor die where lower capacitance may improve the performance of the components in the targeted location (e.g., improved switching speed). The semiconductor die may then be packaged in a polymer including a high thermal conductivity filler after application of the low dielectric constant filler. The application of the polymer including a low dielectric constant filler may help reduce gate capacitance and improve switching speeds in a wire bond or panel level package of multiple die. By using the polymer including a low dielectric constant filler in targeted areas of the semiconductor die, heat dissipation across the entire semiconductor die may not be adversely affected. The combination of a first polymer including a low dielectric constant filler in targeted areas and a second polymer including a high thermal conductivity filler packaging the semiconductor die may be used in a variety of applications including power conversion applications, insulated gate bipolar transistor (IGBT) with diode applications, silicon carbide (SiC) junction field-effect transistor (JFET) with cascaded silicon field-effect transistor (FET) applications, multideck product applications, or any other application where performance may be improved through the use of a low dielectric constant polymer.

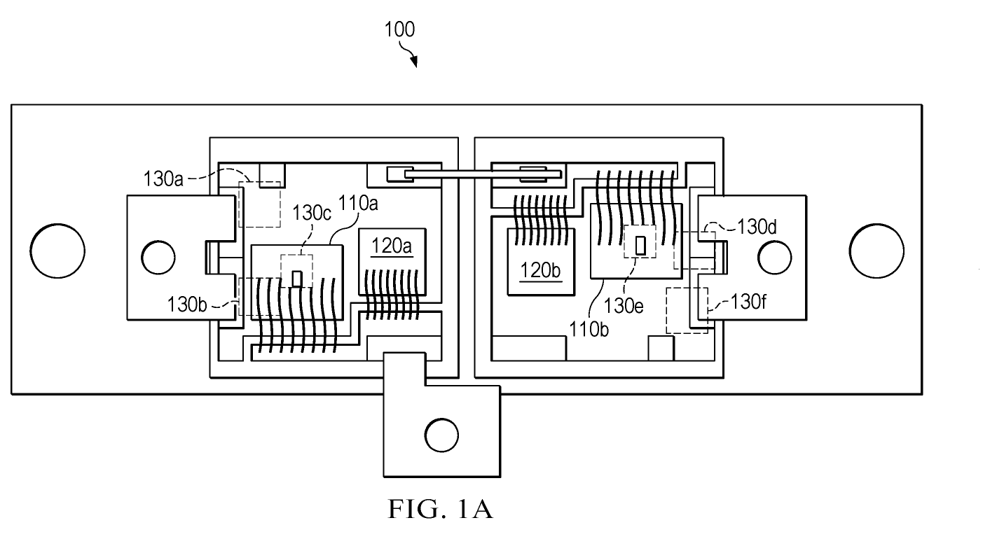

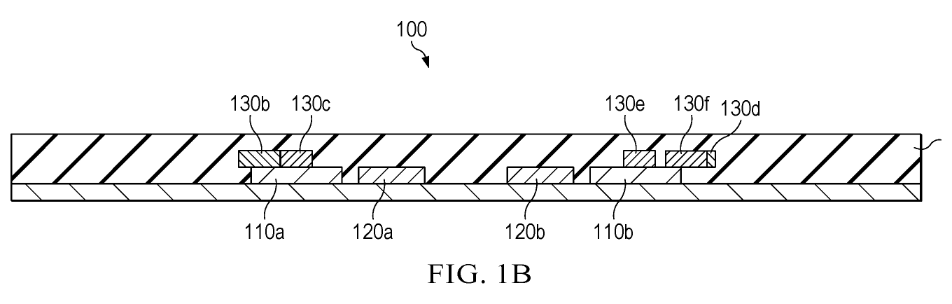

FIGS. 1A and 1B illustrate top and side views, respectively, of a semiconductor die packaged using a first polymer having a low dielectric constant filler in targeted areas, according to examples of the present disclosure. Semiconductor die 100 may include insulated gate bipolar transistor (IGBT) 110 and diode 120. The performance of transistor 110 may be improved by applying a low dielectric constant polymer in targeted areas on or near transistor 110. For example, switching speeds of transistor 110 may be improved and the gate capacitance of transistor 110 may be reduced. After the low dielectric constant polymer is applied in targeted areas (e.g., adjacent to transistor 110), semiconductor die 100 may be packaged with a second polymer having a filler for improved heat transfer.

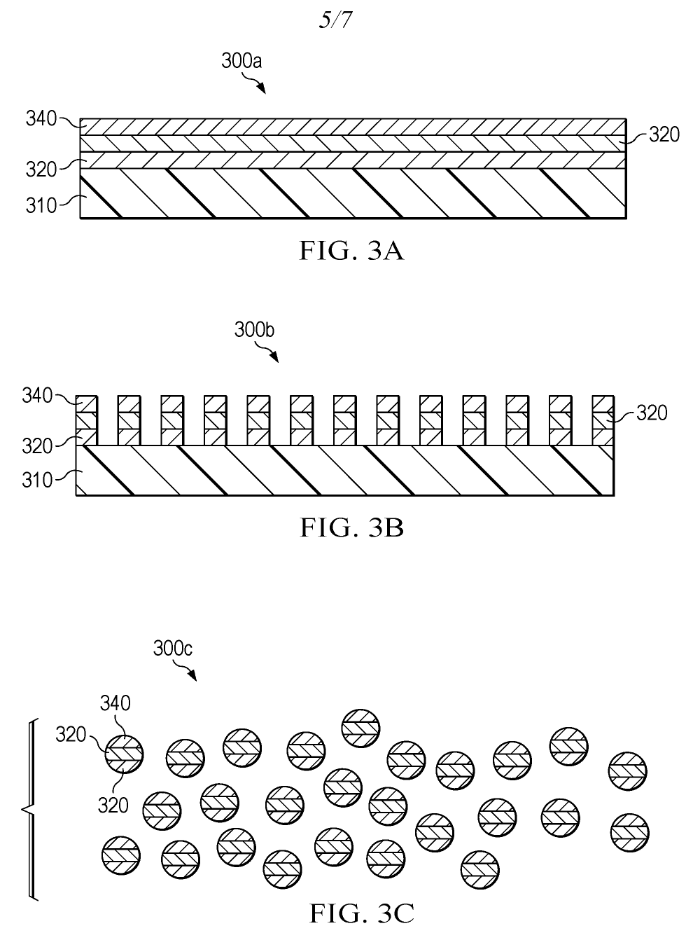

Semiconductor die 100 may include a first polymer including a base resin and a low dielectric constant filler applied in targeted areas 130a, 130b, 130c, 130d, 130e, and 130f. The first polymer may have a dielectric constant of 3.3 or less. The base resin may be any suitable resin, such as, but not limited to, Novolac resins, bisphenol, polyimide, or any combination thereof. The low dielectric constant filler may be created using the process described with respect to FIGS. 3A, 3B, and 3C. Alternatively, or additionally, the low dielectric constant filler may be, for example, Siloxane, Organosilicate glass, fluorine doped silicon dioxide, or any combination thereof. The first polymer may be applied to targeted areas 130a, 130b, 130c, 130d, 130e, and 130f using additive manufacturing techniques, including, but not limited to, inkjet material deposition or three dimensional (3D) printing. The inkjet process may involve a nozzle that deposits droplets of the low dielectric constant polymer at targeted areas 130a, 130b, 130c, 130d, 130e, and 130f. The 3D printing process may use any suitable 3D printing technique including, but not limited to, fused deposition modeling (FDM), stereolithography (SLA), selective laser sintering (SLS), selective laser melting (SLM), binder jetting, and material jetting. The use of additive manufacturing techniques may allow the first polymer to be applied in the targeted areas in a cost effective manner.

Targeted areas 130a, 130b, 130c, 130d, 130e, and 130f may be selected by simulating the operation of semiconductor die 100 to identify areas that may benefit from the use of the first polymer to reduce the dielectric constant in certain areas, including but not limited to, areas having noise, parasitic capacitance, or any combination thereof. For example, a circuit designer or manufacturer may use an Electronic Design Automation (EDA) tool (e.g., a Cadence, Synopsys, or Ansys EDA platform) to design a circuit on semiconductor die 100. The circuit designer may then use the EDA tool to identify portions of semiconductor die 100 expected to have noise, parasitic capacitance, or any combination thereof. The circuit designer may determine whether the expected noise or parasitic capacitance (or both) may be reduced by applying the first polymer in targeted areas of semiconductor die 100. The circuit designer may then determine the size and location of the targeted areas 130a, 130b, 130c, 130d, 130e, and 130f that accomplish the circuit designer’s goals of reduced noise, parasitic capacitance, or any combination thereof.

A second polymer having a heat transfer enhanced filler may be applied over targeted areas 130a, 130b, 130c, 130d, 130e, and 130f and semiconductor die 100 to encapsulate semiconductor die 100. The second polymer may be formed of a base resin including fillers with high thermal conductivity, such as aluminum oxide (e.g., Al₂O₃), aluminum, aluminum nitride (e.g., AlN), boron nitride (e.g., BN), silicon dioxide (SiO₂), diamond, other encapsulated metal fillers, other oxidized metal fillers, or any combination thereof. The base resin may be any suitable resin, such as, but not limited to, Novolac resins, bisphenol, polyimide, or any combination thereof. The thermal conductivity of the second polymer may be less than 2,200 Watts per meter-Kelvin (W/m-K) at zero degrees Kelvin.

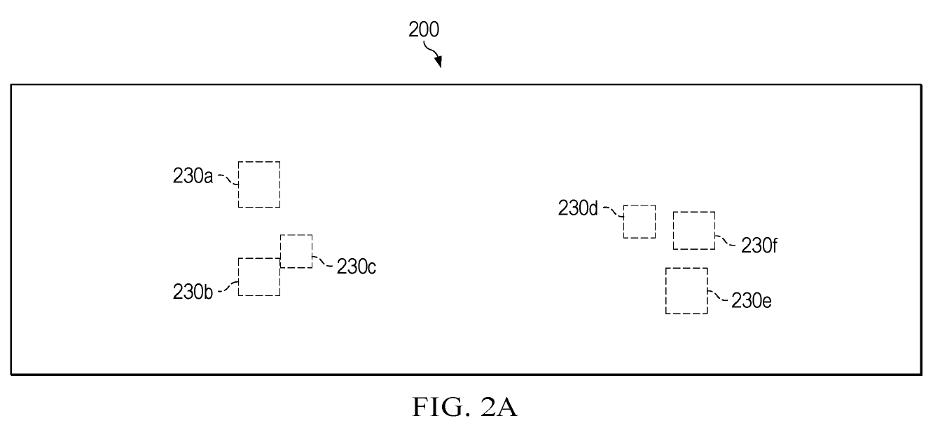

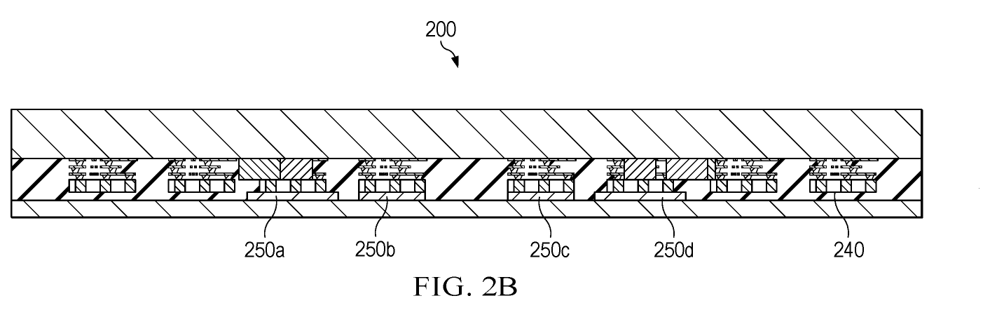

FIGS. 2A and 2B illustrate top and side views, respectively, of a redistribution layer in a panel level package, according to examples of the present disclosure. Semiconductor die 200 may include redistribution layer (RDL) 240. RDL 240 may be used to route input/output (I/O) connections of integrated circuits 250a, 250b, 250c, and 250d on semiconductor die 200. A first polymer having a low dielectric constant, such as a polymer including fillers created using the process shown in FIGS. 3A, 3B, and 3C or, for example, Siloxane, Organosilicate glass, fluorine doped silicon dioxide, or any combination thereof, may be applied to targeted areas 230a, 230b, 230c, 230d, 230e, and 230f using additive manufacturing. By applying the first polymer to targeted areas 230a, 230b, 230c, 230d, 230e, and 230f, gate capacitance (e.g., capacitance between source and drain, capacitance between gate and source, and capacitance between gate and drain) may be locally reduced in targeted areas 230a, 230b, 230c, 230d, 230e, and 230f. For example, targeted areas 230a, 230b, 230c, 230d, 230e, and 230f may adjacent to an intermediate layer of RDL 240 such that the first polymer is applied on an intermediate layer of RDL 240.

After application of the first polymer to targeted areas 230a, 230b, 230c, 230d, 230e, and 230f, semiconductor die 200 may be packaged using a heat transfer enhanced polymer. The heat transfer enhanced polymer may be applied to encapsulate semiconductor die 200 and may be applied using any suitable method including, but not limited to, epoxy molding techniques.

The polymer having a heat transfer enhanced filler may be formed of a base resin including fillers with high thermal conductivity, such as aluminum oxide (e.g., Al₂O₃), aluminum, aluminum nitride (e.g., AlN), boron nitride (e.g., BN), silicon dioxide (SiO₂), other encapsulated metal fillers, other oxidized metal fillers, or any combination thereof.

FIGS. 3A, 3B, and 3C illustrate the creation of a filler for a polymer having a low dielectric constant, according to examples of the present disclosure. A polymer having a low dielectric constant may be formed of a base resin with a low dielectric constant filler. The filler may be created using low dielectric constant materials. For example, as shown in FIG. 3A, first layer 320 of a first low dielectric constant material, such as Black Diamond 3™ from Applied Materials, Inc., may be applied on silicon base 310. The first low dielectric constant material may have a dielectric constant of 3.3 or less. Second layer 330 of a second low dielectric constant material, such as Black Diamond 2™ from Applied Materials, Inc., may be applied on top of first layer 320. The second low dielectric constant material may have a dielectric constant of 3.3 or less. Third layer 340 of the first low dielectric constant material may be applied on top of second layer 330.

The first low dielectric constant material and the second low dielectric constant material may be selected such that the wet etch rate of the first low dielectric constant material is different from and faster than the wet etch rate of the second low dielectric constant material. In some examples, the third layer may be made of a third low dielectric constant material having a wet etch rate that is substantially the same as the wet etch rate of the first dielectric material.

While three layers of low dielectric materials are shown in FIGS. 3A, 3B, and 3C, the filler may be created using more than three layers. The layers may have symmetric wet etch rates from top to bottom such that the wet etch rates of the outer most layers is substantially the same, the wet etch rates of the next outer most layers is substantially the same and slower than the wet etch rates of the outer most layers, and so on. For example, the filler may be created with five layers where the first and fifth layers have a first wet etch rate, the second and fourth layers have a second wet etch rate that is slower than the first wet etch rate, and the third layer has a third wet etch rate that is slower than the second wet etch rate.

As shown in FIG. 3B, a pattern may be wet etched into first layer 320, second layer 330, and third layer 340. The pattern may be any suitable pattern that creates a plurality of columns of first layer 320, second layer 330, and third layer 340, such as a grid pattern.

As shown in FIG. 3C, first layer 320, second layer 330, and third layer 340 may be removed from silicon base 310 and may form balls of low dielectric constant filler that may be added to a base resin to form a polymer having a low dielectric constant. The balls may be formed due to the varying wet etch rates of the materials used in first layer 320, second layer 330, and third layer 340. The polymer may then be applied at targeted areas of a semiconductor die during the packaging process, such as targeted areas 130a, 130b, 130c, 130d, 130e, and 130f shown in FIG. 1.

In some examples, rather than forming a filler using the steps described with respect to FIGS. 3A, 3B, and 3C, hollow silicon dioxide (SiO₂) spheres, Siloxane, Organosilicate glass, fluorine doped silicon dioxide, or any combination thereof may be used as the low dielectric filler material.

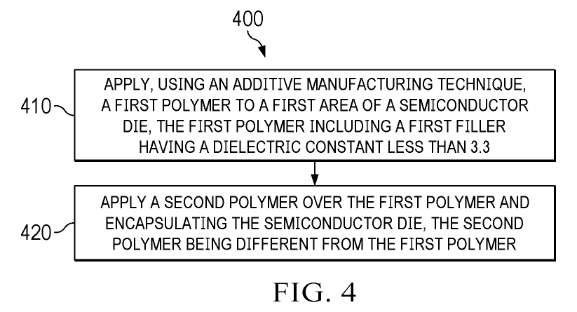

FIG. 4 illustrates a method performed for providing a polymer including a low dielectric constant in targeted areas of a semiconductor using additive manufacturing and encasing the semiconductor die with a second polymer having a high thermal conductivity, according to examples of the present disclosure. Method 400 may be implemented using an additive manufacturing technique, including, but not limited to, inkjet material deposition, three dimensional (3D) printing, fused deposition modeling (FDM), stereolithography (SLA), selective laser sintering (SLS), selective laser melting (SLM), binder jetting, and material jetting in combination with any other system operable to implement method 400. Although examples have been described above, other variations and examples may be made from this disclosure without departing from the spirit and scope of these disclosed examples.

Method 400 may begin at block 410 where a first polymer may be applied to a first area of a semiconductor die using an additive manufacturing technique. The first polymer may include a base resin and a first filler that has a dielectric constant of 3.3 or less. The base resin may be any suitable resin, such as, but not limited to, Novolac resins, bisphenol, polyimide, or any combination thereof. The first filler may be created using the process described with respect to FIGS. 3A, 3B, and 3C. Alternatively, or additionally, the first filler may be, for example, Siloxane, Organosilicate glass, fluorine doped silicon dioxide, or any combination thereof. The additive manufacturing technique may be any suitable additive manufacturing technique, such as, but not limited to, inkjet material deposition, 3D printing, FDM, SLA, SLS, SLM, binder jetting, material jetting, or any combination thereof.

At block 420, a second polymer may be applied over the first polymer to encapsulate the semiconductor die. The second polymer may be applied using any suitable method including, but not limited to, epoxy molding techniques. The second polymer may be different from the first polymer and may include a heat-transfer enhanced filler. For example, the second polymer may be formed of a base resin including fillers with high thermal conductivity, such as aluminum oxide (e.g., Al₂O₃), aluminum, aluminum nitride (e.g., AlN), boron nitride (e.g., BN), silicon dioxide (SiO₂), diamond, other encapsulated metal fillers, other oxidized metal fillers, or any combination thereof. The base resin may be any suitable resin, such as, but not limited to, Novolac resins, bisphenol, polyimide, or any combination thereof. The thermal conductivity of the second polymer may be less than 2,200 Watts per meter-Kelvin (W/m-K) at zero degrees Kelvin.

Although FIG. 4 discloses a particular number of operations related to method 400, method 400 may be executed with greater or fewer operations than those depicted in FIG. 4. In addition, although FIG. 4 discloses a certain order of operations to be taken with respect to method 400, the operations comprising method 400 may be completed in any suitable order.

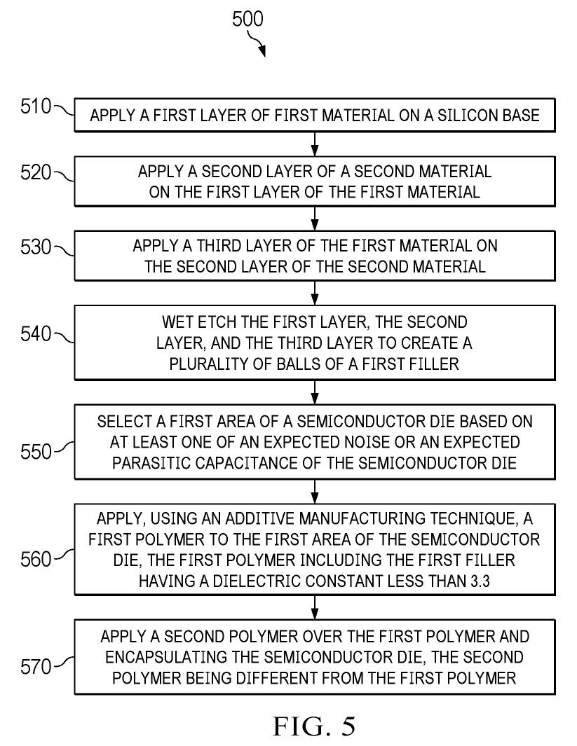

FIG. 5 illustrates a more detailed method performed for providing a polymer including a low dielectric constant in targeted areas of a semiconductor using additive manufacturing and encasing the semiconductor die with a second polymer having a high thermal conductivity, according to examples of the present disclosure. Method 500 may be implemented using an additive manufacturing technique, including, but not limited to, inkjet material deposition, 3D printing, FDM, SLA, SLS, SLM, binder jetting, and material jetting in combination with any other system operable to implement method 500. Although examples have been described above, other variations and examples may be made from this disclosure without departing from the spirit and scope of these disclosed examples.

Method 500 may begin at block 510, where a first layer of a first material may be applied on a silicon base. The first material may be a low dielectric constant material, such as Black Diamond 3™ from Applied Materials, Inc. and may have a dielectric constant of 3.3 or less. The first material may have a first wet etch rate.

At block 520, a second layer of a second material may be applied on the first layer of the first material (from block 510). The second material may be a second low dielectric constant material, such as Black Diamond 2™ from Applied Materials, Inc. The second material may have a dielectric constant of 3.3 or less. The second material may have a second wet etch rate that is slower than the first wet etch rate of the first material.

At block 530, a third layer of the first material may be applied on the second layer of the second material (from block 520). In some examples the third layer may be a third material having a low dielectric constant instead of a second layer of the first material. The third material may have a third wet etch rate that is substantially the same as the first wet etch rate of the first material.

In some examples, additional layers may be applied to the silicon base. The layers may have symmetric wet etch rates from top to bottom such that the wet etch rates of the outer most layers is substantially the same, the wet etch rates of the next outer most layers is substantially the same and slower than the wet etch rates of the outer most layers, and so on. For example, the filler may be created with five layers where the first and fifth layers have a first wet etch rate, the second and fourth layers have a second wet etch rate that is slower than the first wet etch rate, and the third layer has a third wet etch rate that is slower than the second wet etch rate.

At block 540, the first layer, the second layer, and the third layer may be wet etched to create a plurality of balls to form a first filler. The wet etching may create a pattern in the first layer, the second layer, and the third layer. After wet etching the first layer, the second layer, and the third layer, the first layer, the second layer, and the third layer may be removed from the silicon base and may form a plurality of balls of the first filler. The balls may be formed due to the varying wet etch rates of the first and second materials used in the first layer, the second layer, and the third layer. The balls of the first filler may be added to a base resin to create a first polymer having a low dielectric constant.

At block 550, a first area of a semiconductor die may be selected based on at least one of an expected noise or an expected parasitic capacitance of the semiconductor die. For example, a circuit designer or manufacturer may use an Electronic Design Automation (EDA) tool (e.g., a Cadence, Synopsys, or Ansys EDA platform) to design a circuit on semiconductor die 100. The circuit designer may then use the EDA tool to identify portions of semiconductor die 100 expected to have noise, parasitic capacitance, or any combination thereof. The circuit designer may determine whether the expected noise or parasitic capacitance (or both) may be reduced by applying the first polymer in targeted areas of semiconductor die 100. The circuit designer may then determine the size and location of the targeted areas 130a, 130b, 130c, 130d, 130e, and 130f that accomplish the circuit designer’s goals of reduced noise, parasitic capacitance, or any combination thereof.

At block 560, a first polymer may be applied to the first area of a semiconductor die (selected at block 550) using an additive manufacturing technique. The first polymer may include the first filler (created at block 540) that has a dielectric constant of 3.3 or less. The first filler may be created using the process described with respect to FIGS. 3A, 3B, and 3C. Alternatively, or additionally, the first filler may be, for example, Siloxane, Organosilicate glass, fluorine doped silicon dioxide, or any combination thereof. The additive manufacturing technique may be any suitable additive manufacturing technique, such as, but not limited to, inkjet material deposition, 3D printing, FDM, SLA, SLS, SLM, binder jetting, material jetting, or any combination thereof.

At block 570, a second polymer may be applied over the first polymer to encapsulate the semiconductor die. The second polymer may be applied using any suitable method including, but not limited to, epoxy molding techniques. The second polymer may be different from the first polymer and may include a heat-transfer enhanced filler. For example, the second polymer may be formed of a base resin including fillers with high thermal conductivity, such as aluminum oxide (e.g., Al₂O₃), aluminum, aluminum nitride (e.g., AlN), boron nitride (e.g., BN), silicon dioxide (SiO₂), diamond, other encapsulated metal fillers, other oxidized metal fillers, or any combination thereof. The thermal conductivity of the second polymer may be less than 2,200 Watts per meter-Kelvin (W/m-K) at zero degrees Kelvin.

Although FIG. 5 discloses a particular number of operations related to method 500, method 500 may be executed with greater or fewer operations than those depicted in FIG. 5. In addition, although FIG. 5 discloses a certain order of operations to be taken with respect to method 500, the operations comprising method 500 may be completed in any suitable order.

Although examples have been described above, other variations and examples may be made from this disclosure without departing from the spirit and scope of these disclosed examples.

What is claimed is:

1. An apparatus, comprising:
a semiconductor die;
a first polymer applied to a first area of the semiconductor die, the first polymer including a first filler having a dielectric constant of 3.3 or less; and
a second polymer encapsulating the semiconductor die and the first polymer, the second polymer being different from the first polymer.

2. The apparatus of claim 1, wherein the second polymer includes a second filler having a thermal conductivity less than 2200 Watts per meter-Kelvin at 0^{o} Kelvin.

3. The apparatus of claim 2, wherein the second filler includes at least one of aluminum oxide (Al₂O₃), aluminum, aluminum nitride (AlN), boron nitride (BN), silicon dioxide, or diamond.

4. The apparatus of claim 1, wherein the first polymer is applied to the first area using an additive manufacturing technique.

5. The apparatus of claim 1, wherein the first filler having the dielectric constant of 3.3 or less is created by a process including:
applying a first layer of a first material on a silicon base;
applying a second layer of a second material on the first layer of the first material;
applying a third layer of the first material on the second layer of the second material; and
wet etching the first layer, the second layer, and the third layer to create a plurality of balls of the first filler.

6. The apparatus of claim 1, wherein the first area of the semiconductor die is selected based on at least one of an expected noise or an expected parasitic capacitance of the semiconductor die.

7. The apparatus of claim 1, wherein the first area of the semiconductor die is adjacent to a transistor on the semiconductor die.

8. The apparatus of claim 1, wherein the first area of the semiconductor die is an intermediate layer of a redistribution layer.

9. A method, comprising:
applying, using an additive manufacturing technique, a first polymer to a first area of a semiconductor die, the first polymer including a first filler having a dielectric constant of 3.3 or less; and
applying a second polymer over the first polymer and encapsulating the semiconductor die, the second polymer being different from the first polymer.

10. The method of claim 9, wherein the second polymer includes a second filler having a thermal conductivity less than 2200 Watts per meter-Kelvin at 0^{o} Kelvin.

11. The method of claim 10, wherein the second filler includes at least one of aluminum oxide (Al₂O₃), aluminum, aluminum nitride (AlN), boron nitride (BN), silicon dioxide, or diamond.

12. The method of claim 9, comprising:
creating the first filler by:
applying a first layer of a first material on a silicon base;
applying a second layer of a second material on the first layer of the first material;
applying a third layer of the first material on the second layer of the second material; and
wet etching the first layer, the second layer, and the third layer to create a plurality of balls of the first filler.

13. The method of claim 9, comprising selecting the first area of the semiconductor die based on at least one of an expected noise or an expected parasitic capacitance of the semiconductor die.

14. The method of claim 9, wherein the first polymer is applied adjacent to a transistor on the semiconductor die.

15. The method of claim 9, wherein the first polymer is applied on an intermediate layer of a redistribution layer.

16. A semiconductor die made by a process comprising:
applying, using an additive manufacturing technique, a first polymer to a first area of a semiconductor die, the first polymer including a first filler having a dielectric constant of 3.3 or less; and
applying a second polymer over the first polymer and encapsulating the semiconductor die, the second polymer being different from the first polymer.

17. The semiconductor die of claim 16, wherein the second polymer includes a second filler having a thermal conductivity less than 2200 Watts per meter-Kelvin at 0^{o} Kelvin.

18. The semiconductor die of claim 16, the process comprising:
creating the first filler by:
applying a first layer of a first material on a silicon base;
applying a second layer of a second material on the first layer of the first material;
applying a third layer of the first material on the second layer of the second material; and
wet etching the first layer, the second layer, and the third layer to create a plurality of balls of the first filler.

19. The semiconductor die of claim 16, wherein the first polymer is applied adjacent to a transistor on the semiconductor die.

20. The semiconductor die of claim 16, wherein the first polymer is applied on an intermediate layer of a redistribution layer.
